(19) United States
(12) Patent Application Publication
(10) Pub. No.: US 2017/0170310 A1
(43) Pub. Date: Jun. 15, 2017

(54) SEMICONDUCTOR DEVICE AND MANUFACTURING METHOD OF THE SEMICONDUCTOR DEVICE

(71) Applicant: HYUNDAI MOTOR COMPANY, Seoul (KR)

(72) Inventors: Dae Hwan CHUN, Gwangmyeong-si (KR); Youngkyun JUNG, Seoul (KR); NackYong JOO, Hanam-si (KR); Junghee PARK, Suwon-si (KR); JongSeok LEE, Suwon-si (KR)

(21) Appl. No.: 15/165,912

(22) Filed: May 26, 2016

(30) Foreign Application Priority Data
Dec. 14, 2015 (KR) 10-2015-0178098

(51) Int. Cl. H01L 29/78; H01L 29/66; H01L 21/04; H01L 29/16

(52) U.S. Cl. CPC H01L 29/7806; H01L 29/1608; H01L 29/7813; H01L 29/66068; H01L 21/047

(57) ABSTRACT

A semiconductor device includes an n− type layer disposed in a first surface of an n+ type silicon carbide substrate, a first trench and a second trench disposed in the n− type layer and spaced apart from each other, a p type region surrounding a lateral surface and a corner of the first trench, an n+ type region disposed on the p type region and the n− type layer between the first trench and the second trench, a gate insulating layer disposed in the second trench, a gate electrode disposed on the gate insulating layer, an oxide layer disposed on the gate electrode, a source electrode disposed on the oxide layer and the n+ type region, and disposed in the first trench, and a drain electrode disposed in a second surface of the n+ type silicon carbide substrate, wherein the source electrode contacts the n− type layer.

### CROSS-REFERENCE TO RELATED APPLICATION

This application claims the benefit of priority to Korean Patent Application No. 10-2015-0178098, filed with the Korean Intellectual Property Office on Dec. 14, 2015, the entire contents of which are incorporated herein by reference.

### TECHNICAL FIELD

The present disclosure relates to a semiconductor device including a silicon carbide (SiC) and a manufacturing method thereof.

### BACKGROUND

A power semiconductor device is required to have low turn-on resistance or a low saturated voltage in order to reduce power loss in a conductive state while a large amount of current flows. Further, the power semiconductor device is required to have an ability to endure an inverse directional high voltage at a PN conjunction thereof, which may be applied to opposite terminals of the power semiconductor device when it is turned off or when a switch is turned off, that is, to have a high breakdown voltage characteristic.

When various power semiconductor devices satisfying electrical and physical conditions are packaged in one module, the number of semiconductor devices included in the packaged module and electrical specifications thereof may vary depending on conditions required by a system.

Generally, a three-phase power semiconductor module is used so as to generate a Lorentz force for driving a motor. That is, the three-phase power semiconductor module controls a current and power applied to the motor, such that a driven state of the motor is determined.

Although conventional silicon insulated gate bipolar transistors (IGBTs) and silicon diodes have been included and used in such a three-phase semiconductor module, the three-phase semiconductor module has recently tended to include silicon carbide (SiC) metal oxide semiconductor field effect transistors (MOSFETs) and silicon carbide diodes in order to minimize a power consumption therein and to increase a switching speed thereof.

When the silicon IGBTs or silicon carbide MOSFETs are connected to separate diodes, a plurality of wires are required for the connection, and since parasitic capacitance and inductance occur due to the plurality of wires, the switching speed of the module may be reduced.

The above information disclosed in this Background section is only to enhance the understanding of the background of the disclosure and therefore it may contain information that does not form the prior art that is already known in this country to a person of ordinary skill in the art.

### SUMMARY

The present disclosure has been made in an effort to provide a silicon carbide semiconductor device including a MOSFET region and a diode region.

An exemplary embodiment of the present disclosure provides a semiconductor device including: an n− type layer disposed in a first surface of an n+ type silicon carbide substrate; a first trench and a second trench that are disposed in the n− type layer and are spaced apart from each other; a p type region surrounding a lateral surface and a corner of the first trench; an n+ type region disposed on the p type region and the n− type layer between the first trench and the second trench; a gate insulating layer disposed in the second trench; a gate electrode disposed on the gate insulating layer; an oxide layer disposed on the gate electrode; a source electrode that is disposed on the oxide layer and the n+ type region and that is disposed in the first trench; and a drain electrode disposed in a second surface of the n+ type silicon carbide substrate, wherein the source electrode may contact the n− type layer disposed under the first trench.

The semiconductor device may further include a low-concentration n− type disposed between the n− type layer and the n+ type region.

A doped concentration of the low-concentration n− type layer may be smaller than that of the n− type layer.

The low-concentration n− type layer may be disposed between the second trench and the p type region.

The semiconductor device may further include a p+ type region disposed between the p type region and the first trench.

The p+ type region may surround a lateral surface and a corner of the first trench.

The source electrode may include a Schottky electrode and an ohmic electrode disposed on the Schottky electrode.

The Schottky electrode may contact the n− type layer disposed under the first trench.

Another embodiment of the present disclosure provides A manufacturing method of a semiconductor device, including: sequentially forming an n− type layer and a low-concentration n− type layer in a first surface of an n+ type silicon carbide substrate; forming an n+ type region on the low-concentration n− type layer; forming a first trench and a second trench spaced apart from each other by etching the n+ type region and the low-concentration n− type layer; forming a p type region to surround a lateral surface and a corner of the first trench; forming a gate insulating layer in the second trench; forming a gate electrode on the gate insulating layer; forming an oxide layer on the gate electrode; forming a source electrode on the oxide layer and the n+ type region and at the first trench; and forming a drain electrode in a second surface of the n+ type silicon carbide substrate, wherein a plurality of the p type regions may be spaced apart from each other, and the source electrode may contact the n− type disposed under the first trench.

In the forming of the p type region, p ions may be injected by a tilt ion injecting method.

The manufacturing method of the semiconductor device may further include forming a p+ type region between the p type region and the first trench.

In the forming of the p+ type region, p+ ions may be injected by a tilt ion injecting method.

According to the embodiment of the present disclosure, the semiconductor device does not need to have wires for connecting MOSFET devices and diode devices because of including the MOSFET region and the diode region therein. Accordingly, a size of the semiconductor device may be reduced.

Further, according to the embodiment of the present disclosure, since the MOSFET region and the diode region are included in one semiconductor device without a wire, a switching speed of the semiconductor device may be improved.

### BRIEF DESCRIPTION OF THE DRAWINGS

FIG. 1 illustrates a schematic cross-sectional view of a semiconductor device according to an exemplary embodiment of the present disclosure.

FIG. 2 illustrates a schematic cross-sectional view of a semiconductor device according to another exemplary embodiment of the present disclosure.

FIGS. 3 to 7 illustrate schematic cross-sectional views of a manufacturing method of the semiconductor device illustrated in FIG. 2.

### DETAILED DESCRIPTION

The present disclosure will be described more fully hereinafter with reference to the accompanying drawings, in which exemplary embodiments of the disclosure are shown. However, it is to be understood that the disclosure is not limited to the disclosed embodiments, but, on the contrary, is intended to also cover various modifications. As those skilled in the art would realize, the described embodiments may be modified in various different ways, all without departing from the spirit or scope of the present disclosure.

In the drawings, the thickness of layers, films, panels, regions, etc., may be exaggerated for clarity. It will be understood that when an element such as a layer, film, region, or substrate is referred to as being “on” another element, it can be directly on the other element or intervening elements may also be present.

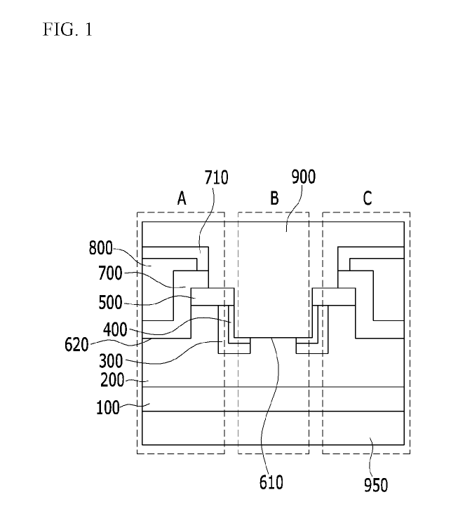

FIG. 1 illustrates a schematic cross-sectional view of a semiconductor device according to an exemplary embodiment of the present disclosure.

Referring to FIG. 1, a semiconductor device according to an exemplary embodiment may include metal oxide silicon field effect transistor (MOSFET) regions (A) and a diode region (B) that are adjacent to each other.

Hereinafter, a detailed structure of the semiconductor device according to an exemplary embodiment will be described.

The semiconductor device according to the present exemplary embodiment may include an n+ type silicon carbide substrate 100, an n− type layer 200, a p type region 300, a p+ type region 400, an n+ type region 500, a gate electrode 800, a source electrode 900 and a drain electrode 950.

The n− type layer 200 may be disposed on a first surface of the n+ type silicon carbide substrate 100, and a first trench 610 and a second trench 620 that may be spaced apart from each other may be disposed in the n− type layer 200.

The p type region 300 may be disposed at a lateral surface of the first trench 610 and may surround a corner of the first trench 610. The p+ type region 400 may be disposed between the p type region 300 and the first trench 610. That is, the p+ type region 400 may also be disposed at the lateral surface of the first trench 610 and may surround the corner of the first trench 610.

The n+ type region 500 may be disposed on the p type region 300, the p+ type region 400, and the n− type layer 200 between the first trench 610 and the second trench 620.

A gate insulating layer 700 may be disposed in the second trench 620. The gate electrode 800 may be disposed on the gate insulating layer 700. An oxide layer 710 may be disposed on the gate electrode 800. The oxide layer 710 may cover a lateral surface of the gate electrode 800.

The source electrode 900 may be disposed on the n+ type region 500 and the oxide layer 710, and may be disposed in the first trench 610. The source electrode 900 may include the Schottky metal and an ohmic metal positioned on the Schottky metal. The Schottky metal may be positioned only in the first trench 610.

The drain electrode 950 may be disposed in a second surface of the n+ type silicon carbide substrate 100. The drain electrode 950 may include an ohmic metal. Here, the second surface of the n+ type silicon carbide substrate 100 may be a surface opposite to the first surface of the n+ type silicon carbide substrate 100.

The n− type layer 200, the p type region 300, the n+ type region 500, the gate electrode 800, the source electrode 900, and the drain electrode 950 may form the MOSFET region (A), and the n− type layer 200, the p type region 300, the p+ type region 400, the source electrode 900, and the drain electrode 950 may form the diode region (B). In the diode region (B), the source electrode 900 may contact the n− type layer 200 under the first trench 610. That is, in the diode region (B), the Schottky metal of the source electrode 900 may contact the n− type layer 200 under the first trench 610.

The MOSFET region (A) and the diode region (B) may separately operate according to a state in which a voltage is applied to the semiconductor device according to a present exemplary embodiment.

When a voltage of 0 V or a voltage equal to or less than a threshold voltage of the MOSFET is applied to the gate electrode, a positive voltage may be applied to the source electrode, and a voltage of 0 V may be applied to the drain electrode, the diode region (B) may operate. When the diode region (B) operates, a current may be output from the n− type layer 200 under the first trench 610.

When a voltage of equal to or greater than the threshold voltage of the MOSFET is applied to the gate electrode, a voltage of 0 V may be applied to the source electrode, and a positive voltage may be applied to the drain electrode and the MOSFET region (A) may operate. When the MOSFET region (A) operates, a current may be output from the n− type layer 200 under the second trench 620.

As such, since the semiconductor device according to a present exemplary embodiment includes the MOSFET region (A) and the diode region (B), it is possible to eliminate a wire for connecting a conventional MOSFET device and a diode device. Accordingly, an area of the semiconductor device may be reduced.

In addition, since the MOSFET region and the diode region may be included in one semiconductor device without the wire, a switching speed of the semiconductor device may be improved.

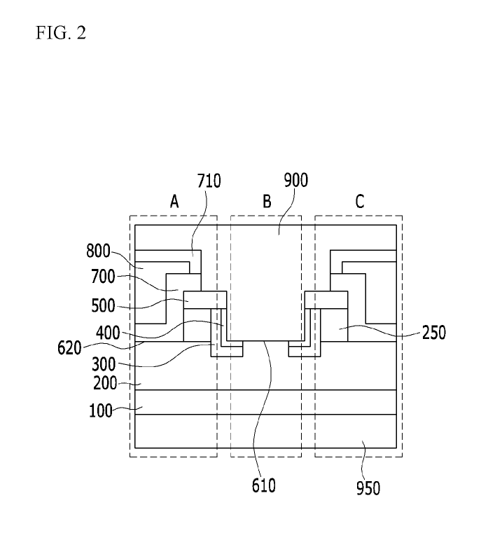

The semiconductor device may include a low-concentration n− type layer having a concentration of less than that of the n− type layer. A semiconductor device including the low-concentration n− type layer will now be described with reference to FIG. 2.

FIG. 2 illustrates a schematic cross-sectional view of a semiconductor device according to another exemplary embodiment of the present disclosure.

Referring to FIG. 2, the semiconductor device according to another exemplary embodiment of the present disclosure may be substantially the same as the semiconductor device of FIG. 1, except for a low-concentration n− type layer 250. Accordingly, duplicated descriptions of the same portions will be omitted.

The low-concentration n− type layer 250 may be disposed between the n− type layer 200 and the n+ type region 500. In addition, the low-concentration n− type layer 250 may be disposed between the second trench 620 and the p type region 300. A doped concentration of the low-concentration n− type layer 250 may be smaller than that of the n− type layer 200.

Hereinafter, characteristics of the semiconductor device according to an exemplary embodiment, a typical diode device, and a typical MOSFET device will be compared and described with reference to Table 1.

Table 1 represents respective simulation results for the semiconductor device according to a present exemplary embodiment, a typical diode device, and a typical MOSFET device.

Comparative Example 1 is the typical diode device, and Comparative Example 2 is the typical MOSFET device.

Exemplary Embodiment 1 is a semiconductor device including a single n−-layer, and Exemplary Embodiment 2 is a semiconductor device including dual n− type layers, that is, an n− type layer and a low-concentration n− type layer.

In Table 1, current densities of respective semiconductor devices of Exemplary Embodiment 1, Exemplary Embodiment 2, Comparative Example 1, and Comparative Example 2 are compared in a state in which the same breakdown voltage is applied to the respective semiconductor devices.

TABLE 1

| | | | | Electrical |
|---|---|---|---|---|
| | | | Current | conductive |
| | | Breakdown | density | area (cm²) |
| | | voltage (V) | (A/cm²) | @ 100 A |
| Comparative Example 1 | | 1541 | 305 | 0.33 |
| Comparative Example 2 | | 1538 | 502 | 0.20 |
| Exemplary | Diode | 1549 | 300 | 0.33 |
| Embodiment 1 | operation | | | |
| | MOSFET | | 762 | |
| | operation | | | |
| Exemplary | Diode | 1539 | 434 | 0.24 |
| Embodiment 2 | operation | | | |
| | MOSFET | | 1004 | |
| | operation | | | |

Referring to Table 1, with respect to a current amount of about 100 A, an electrical conductive area of the diode device according to Comparative Example 1 is about 0.33 cm², and an electrical conductive area of the MOSFET device according to Comparative Example 2 is about 0.20 cm². A sum of the electrical conductive areas according to Comparative Example 1 and Comparative Example 2 is about 0.53 cm² when the current amount of the semiconductor devices is about 100 A.

In the case of the semiconductor device according to Exemplary Embodiment 1, an electrical conductive area with respect to the current amount of about 100 A is about 0.33 cm² while the diode operates, and the electrical conductive area with respect to the current amount of about 100 A is about 0.13 cm² while the MOSFET operates. In the case of the semiconductor device according to Exemplary Embodiment 1, when an area of the semiconductor device is about 0.33 cm², it can be seen that a current amount thereof is about 100 A while the diode operates and the current amount thereof is about 251 A while the MOSFET operates.

In the case of the semiconductor device according to Exemplary Embodiment 2, an electrical conductive area with respect to the current amount of about 100 A is about 0.23 cm² while the diode operates, and the electrical conductive area with respect to the current amount of about 100 A is about 0.1 cm² while the MOSFET operates. In the case of the semiconductor device according to Exemplary Embodiment 2, when an area of the semiconductor device is about 0.23 cm², it can be seen that a current amount thereof is about 100 A while the diode operates and the current amount thereof is about 231 A while the MOSFET operates.

That is, in the electrical conductive areas with respect to the current amount of about 100 A while the diode and the MOSFET operate, it can be seen that the corresponding area of the semiconductor device according to Exemplary Embodiment 1 is reduced by about 37% with respect to the sum of the corresponding areas of the semiconductor devices according to Comparative Examples 1 and 2. In addition, it can be seen that the corresponding area of the semiconductor device according to Exemplary Embodiment 2 is reduced by about 57% with respect to the sum of the corresponding areas of the semiconductor devices according to Comparative Examples 1 and 2.

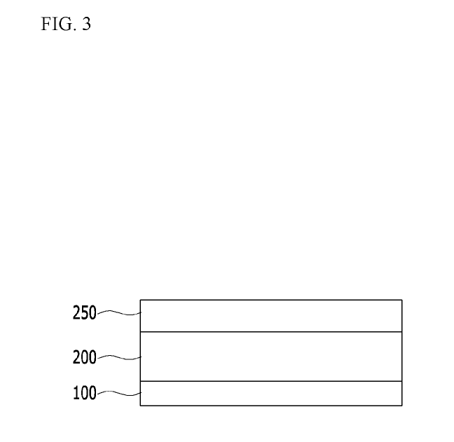

Hereinafter, a manufacturing method of the semiconductor device illustrated in FIG. 2 will be described with reference to FIG. 3 to FIG. 7, and FIG. 2.

FIGS. 3 to 7 illustrate schematic cross-sectional views of a manufacturing method of the semiconductor device illustrated in FIG. 2.

Referring to FIG. 3, the n+ type silicon carbide substrate 100 may be prepared, and after the n− type layer 200 is formed on the first surface of the n+ type silicon carbide substrate 100 by epitaxial growth, the low-concentration n− type layer 250 may be formed on the n− type layer 200 by epitaxial growth. As shown in FIG. 1, the low-concentration n− type layer 250 may be omitted.

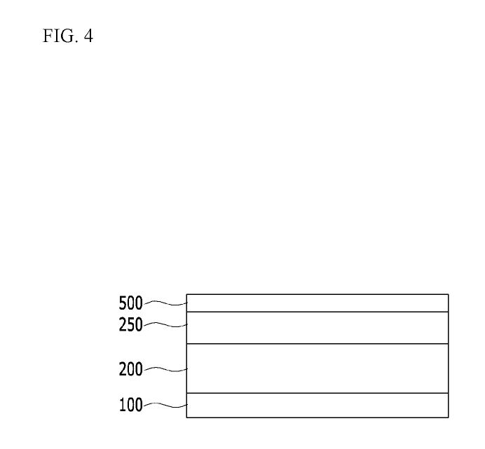

Referring to FIG. 4, the n+ type region 500 may be formed on the low-concentration n− type layer 250. The n+ type region 500 may be formed by injecting n+ ions into the low-concentration n− type layer 250, or may be formed on the low-concentration n− type layer 250 by epitaxial growth.

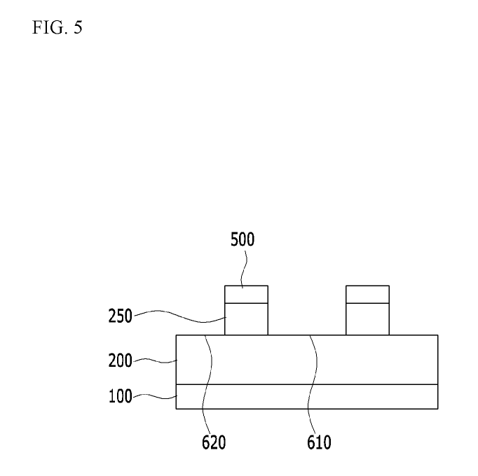

Referring FIG. 5, the first trench 610 and the second trench 620 may be formed by etching the n+ type region 500 and the low-concentration n− type layer 250. In this case, the first trench 610 and the second trench 620 may be simultaneously formed.

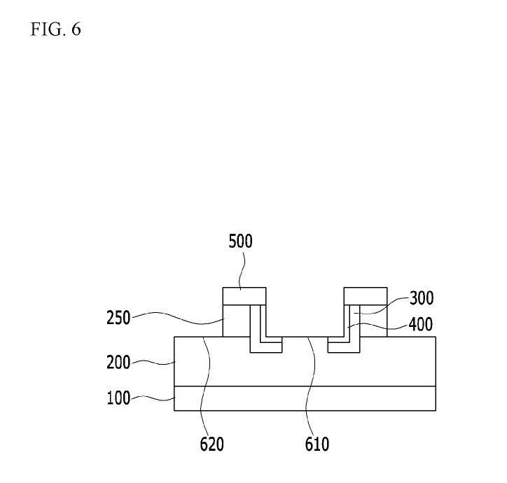

Referring to FIG. 6, the p type region 300 may be formed by injecting p ions into the lateral surface and the corner of the first trench 610, and then the p+ type region 400 may be formed by injecting p+ ions into the lateral surface and the corner of the first trench 610. In this case, the p type region 300 and the p+ type region 400 may be formed to surround the lateral surface and the corner of the first trench 610. Further, the p+ type region 400 may be formed between the p type region 300 and the first trench 610. Here, the p ions and the p+ ions may be injected by a tilt ion injecting method. The tilt ion injecting method may be one having a smaller injecting angle than a right angle with respect to a horizontal surface.

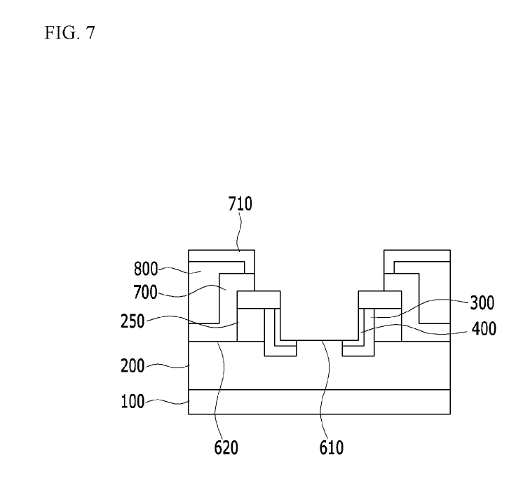

Referring to FIG. 7, after the gate insulating layer 700 is formed at the second trench 620, the gate electrode 800 may be formed on the gate insulating layer 700, and then the oxide layer may be formed on the gate electrode 800.

Referring to FIG. 2, the source electrode 900 may be formed on the oxide layer 710, the n+ type region 500, and the first trench 610, and the drain electrode 950 may be formed on the second surface of the n+ type silicon carbide substrate 100.

In the manufacturing method of the semiconductor device according to a present exemplary embodiment, after the first trench 610 and the second trench 620 are simultaneously formed, even though the p type region 300 and the p+ type region 400 are formed, the present disclosure is not limited thereto, and after the first trench 610 is first formed, the p type region 300 and the p+ type region 400 may be formed, and then the second trench 620 may be formed.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
an n− type layer disposed in a first surface of an n+ type silicon carbide substrate;
a first trench and a second trench disposed in the n− type layer and spaced apart from each other;
a p type region surrounding a lateral surface and a corner of the first trench;
an n+ type region disposed on the p type region and the n− type layer between the first trench and the second trench;
a gate insulating layer disposed in the second trench;
a gate electrode disposed on the gate insulating layer;
an oxide layer disposed on the gate electrode;
a source electrode disposed on the oxide layer and the n+ type region, and disposed in the first trench; and
a drain electrode disposed in a second surface of the n+ type silicon carbide substrate,
wherein the source electrode contacts the n− type layer disposed under the first trench.

2. The semiconductor device of claim 1, further comprising a low-concentration n− type layer disposed between the n− type layer and the n+ type region.

3. The semiconductor device of claim 2, wherein a doped concentration of the low-concentration n− type layer is smaller than that of the n− type layer.

4. The semiconductor device of claim 3, wherein the low-concentration n− type layer is disposed between the second trench and the p type region.

5. The semiconductor device of claim 4, further comprising a p+ type region disposed between the p type region and the first trench.

6. The semiconductor device of claim 5, wherein the p+ type region surrounds a lateral surface and a corner of the first trench.

7. The semiconductor device of claim 1, wherein the source electrode includes a Schottky electrode and an ohmic electrode disposed on the Schottky electrode.

8. The semiconductor device of claim 7, wherein the Schottky electrode contacts the n− type layer disposed under the first trench.

9. A manufacturing method of a semiconductor device, comprising:
sequentially forming an n− type layer and a low-concentration n− type layer in a first surface of an n+ type silicon carbide substrate;
forming an n+ type region on the low-concentration n− type layer;
forming a first trench and a second trench as spaced apart from each other by etching the n+ type region and the low-concentration n− type layer;
forming a p type region to surround a lateral surface and a corner of the first trench;
forming a gate insulating layer in the second trench;
forming a gate electrode on the gate insulating layer;
forming an oxide layer on the gate electrode;
forming a source electrode on the oxide layer and the n+ type region and at the first trench; and
forming a drain electrode in a second surface of the n+ type silicon carbide substrate,
wherein a plurality of the p type regions are spaced apart from each other, and
wherein the source electrode contacts the n− type layer disposed under the first trench.

10. The manufacturing method of the semiconductor device of claim 9, wherein a doped concentration of the low-concentration n− type layer is smaller than that of the n− type layer.

11. The manufacturing method of the semiconductor device of claim 10, wherein in the step of forming the p type region, p ions are injected by a tilt ion injecting method.

12. The manufacturing method of the semiconductor device of claim 11, further comprising forming a p+ type region between the p type region and the first trench.

13. The manufacturing method of the semiconductor device of claim 12, wherein in the step of forming the p+ type region, p+ ions are injected by a tilt ion injecting method.
